(19) United States
(12) Patent Application Publication
(10) Pub. No.: US 2016/0225959 A1
(43) Pub. Date: Aug. 4, 2016

(54) LED Packaging Structure And Method For Manufacturing The Same

(71) Applicant: Everlight Electronics Co., Ltd., New Taipei City (TW)

(72) Inventors: Ke-Hao Pan, New Taipei City (TW); Chi-Ming Wu, New Taipei City (TW)

(21) Appl. No.: 15/014,356

(22) Filed: Feb. 3, 2016

Related U.S. Application Data
(60) Provisional application No. 62/112,053, filed on Feb. 4, 2015.

(51) Int. Cl. H01L 33/50; H01L 29/866; H01L 33/56; H01L 25/16

(52) U.S. Cl. CPC H01L 33/502; H01L 25/167; H01L 29/866; H01L 33/56

(57) ABSTRACT

An LED package having a substrate, an LED chip, a phosphor sheet and a first resin is provided. The LED chip is disposed on the substrate. The phosphor sheet has a first area, and is affixed on a first surface of the LED chip. The first resin is disposed on the substrate for covering the LED chip along with the phosphor sheet, with at least a part of the phosphor sheet being exposed.

### CROSS-REFERENCES TO RELATED APPLICATIONS

This application claims priority to U.S. Provisional Application No. 62/112,053 filed on Feb. 4, 2015.

### TECHNICAL FIELD

The present disclosure relates to light-emitting diode (LED) and, more particularly, to an LED package and a method for manufacturing the same.

### BACKGROUND

Conventionally, to make the light emitted from a LED package have an uniform light-emitting area, a wavelength converting layer (which is usually a resin containing phosphor) is disposed above the LED chip so that the light emitted from the LED chip excite the phosphor in the resin to produce white light, thereby providing desired light sources for users.

To achieve the aforesaid objectives of providing white light and providing a uniform light-emitting area, a known process of manufacturing a LED package includes affixing a phosphor sheet to a top surface of an LED chip, molding with a resin around the LED chip along with the phosphor sheet, and curing the resin so that the LED chip along with the affixed phosphor sheet is surrounded by the first resin with a portion of the phosphor sheet is exposed (i.e., not fully covered by the resin).

However, when affixing the phosphor sheet to the top surface of the LED chip in LED package, the top surface of the LED chip is firstly fully dispensed with adhesive. Such that when the phosphor sheet is placed on and affixed to the top surface of the chip, the adhesive between the top surface of the LED chip along with the phosphor sheet will be pressed and be squeezed out, and thus inevitably smears side surfaces of the chip and the subsequent molding space. This may cause problems such as non-uniform light emission, an opaque periphery of the chip and a thinner resin layer, which lead to lower reliability and yield of the LED package.

Accordingly, providing an LED package and a method for manufacturing the same, which can overcome the non-uniform light emission problem caused by spillover of the resin in the manufacturing process, provide a more uniform light-emitting area and meanwhile improving the reliability and the process yield, as well as provide an LED package which can achieve the same effect without using the phosphor sheet, is needed.

### SUMMARY

The present disclosure describes various implementations of an LED package and fabrication methods thereof.

In one aspect, the light emitted from an LED chip of the LED package may excite a phosphor sheet or a phosphor resin to generate desired white light and provide a uniform light-emitting area.

In another aspect, a phosphor sheet is well adhesive to the LED chip without adhesive spillover, thereby avoiding the contamination problem in the manufacturing process.

Yet in one aspect, a molded phosphor resin instead of a phosphor sheet is used as the material of a wavelength converting layer in an LED packages.

In one aspect, an LED package may include: a substrate, an LED chip disposed on the substrate, a phosphor sheet, a first resin, and an adhesive, wherein the phosphor sheet is affixed to an upper surface of the LED chip via the adhesive.

In some implementations, the first resin may be deposited on the substrate such that the LED chip along with the affixed phosphor sheet is surrounded by the first resin with a portion of the phosphor sheet being exposed.

In some implementations, when affixing the phosphor sheet to the LED chip with the adhesive, the adhesive may not extend over the upper surface of the LED chip.

In one aspect, an LED may include a substrate, an LED chip disposed on the substrate, a phosphor resin disposed on the substrate to cover the LED chip, and a first resin disposed on the substrate to surround the phosphor resin with a part of the phosphor resin being exposed.

In some implementations, the first resin may not be in contact with the LED chip.

In another aspect, an LED package may include a substrate, an LED chip disposed on the substrate, a phosphor coating covering the LED chip, a transparent resin disposed on the substrate to cover the LED chip and the phosphor coating, and a first resin disposed on the substrate to surround the transparent resin with a part of the transparent resin being exposed

In some implementations, the first resin may not be in contact with the LED chip.

In one aspect, a method of fabrication of an LED package may involve operations including the following: providing a substrate; bonding an LED chip onto the substrate; dispensing an adhesive to an upper surface of the LED chip to affix a phosphor sheet to the LED chip; and using a mold to apply pressure onto the phosphor sheet and filling a gap between the substrate and the mold with a first resin. When the mold applies the pressure to the phosphor sheet, the adhesive between the LED chip and the phosphor may not extend over the upper surface of the LED chip, and the first resin may cover the LED chip along with the phosphor sheet and may expose at least a part of the phosphor sheet.

In one aspect, a method of fabrication of an LED package may involve operations including the following: providing a substrate; bonding an LED chip onto the substrate; depositing a phosphor resin on the substrate to cover the LED chip; cutting the phosphor resin along the periphery of the LED chip; and further molding with a first resin on the substrate so that the first resin surrounds the periphery of the phosphor resin with at least a part of the phosphor resin being exposed and the first resin not being in contact with the LED chip.

In one aspect, a method of fabrication of an LED package may involve operations including the following: providing a substrate; bonding an LED chip and a Zener Diode chip adjacent to the LED chip onto the substrate; molding with a phosphor resin on the substrate to cover the LED chip and the Zener Diode chip; cutting the phosphor resin along the periphery of the LED chip and the periphery of the Zener Diode chip; and further molding with a first resin on the substrate so that the first resin surrounds the periphery of the phosphor resin with at least a part of the phosphor resin on the LED chip being exposed and the first resin being not in contact with the LED chip and the Zener Diode chip.

In one aspect, a method of fabrication of an LED package may involve operations including the following: providing a substrate; bonding an LED chip onto the substrate; spraying a phosphor coating on the LED chip; molding with a transparent resin on the substrate to cover the LED chip and the phosphor coating; cutting the transparent resin along the periphery of the LED chip; and further molding with a first resin on the substrate so that the first resin surrounds the periphery of the transparent resin with at least a part of the transparent resin being exposed and the first resin being not in contact with the LED chip.

In one aspect, a method of fabrication of an LED package may involve operations including the following: providing a substrate; bonding an LED chip and a Zener Diode chip adjacent to the LED chip onto the substrate; spraying a phosphor coating on the LED chip; molding with a transparent resin on the substrate to cover the LED chip and the Zener Diode chip; and cutting the transparent resin along the periphery of the LED chip and the periphery of the Zener Diode chip; and further molding with a first resin on the substrate so that the first resin surrounds the periphery of the transparent resin with at least a part of the transparent resin on the LED chip being exposed and the first resin being not in contact with the LED chip and the Zener Diode chip.

The foregoing summary is illustrative only and is not intended to be limiting in any way. That is, the foregoing summary is provided to introduce concepts, highlights, benefits and advantages of the novel and non-obvious techniques described herein. Select implementations are further described below in the detailed description. Thus, the foregoing summary is not intended to identify essential features of the claimed subject matter, nor is it intended for use in determining the scope of the claimed subject matter.

### BRIEF DESCRIPTION OF THE DRAWINGS

The accompanying drawings are included to provide a further understanding of the disclosure, and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 shows a top view of an LED package in accordance with a first implementation of the present disclosure.

FIG. 2 shows a cross-sectional view of a first aspect of the LED package of FIG. 1.

FIG. 2A shows a partially schematic view of a phosphor sheet covering an LED chip in the LED package of FIG. 2.

FIG. 2B shows a partially schematic view of another aspect of the phosphor sheet covering the LED chip in the LED package of FIG. 2.

FIG. 3 shows a cross-sectional view of a second aspect of the LED package of FIG. 1.

FIG. 4A shows a top view of an LED package in accordance with a second implementation of the present disclosure.

FIG. 4B shows a cross-sectional view of the LED package in accordance with the second implementation of the present disclosure.

FIG. 5A shows a top view of an LED package in accordance with a third implementation of the present disclosure.

FIG. 5B shows a cross-sectional view of the LED package in accordance with the third implementation of the present disclosure.

FIG. 6 shows a top view of an LED package in accordance with a fourth implementation of the present disclosure.

FIG. 6A shows a cross-sectional view of a first aspect of the LED package of FIG. 6.

FIG. 6B shows a cross-sectional view of a second aspect of the LED package of FIG. 6.

FIG. 6C shows a cross-sectional view of a third aspect of the LED package of FIG. 6.

FIG. 7A shows a top view of an LED package in accordance with a fifth implementation of the present disclosure.

FIG. 7B shows a cross-sectional view of the LED package in accordance with the fifth implementation of the present disclosure.

FIG. 8 shows a top view of an LED package in accordance with a sixth implementation of the present disclosure.

FIG. 8A shows a cross-sectional view of a first aspect of the LED package of FIG. 8.

FIG. 8B shows a cross-sectional view of a second aspect of the LED package of FIG. 8.

FIG. 8C shows a cross-sectional view of a third aspect of the LED package of FIG. 8.

FIG. 9 shows a process of fabricating an LED package in accordance with a first implementation of the present disclosure.

FIG. 10 shows a process of fabricating an LED package in accordance with a second implementation of the present disclosure.

FIG. 11A shows a process of fabricating an LED package in accordance with a third implementation of the present disclosure.

FIG. 11B shows a process of fabricating an LED package in accordance with yet another implementation of the present disclosure.

FIG. 12 shows a process of fabricating an LED package in accordance with yet another implementation of the present disclosure.

FIG. 13 shows a process of fabricating an LED package in accordance with yet another implementation of the present disclosure.

FIG. 14 shows a process of fabricating an LED package in accordance with yet another implementation of the present disclosure.

### DESCRIPTION OF THE PREFERRED EMBODIMENT

An LED package disclosed in the present disclosure uses an LED chip (e.g., a blue-light LED or an ultraviolet (UV) LED) to emit a light (e.g., blue light or ultraviolet light) so that the emitted light excites a phosphor sheet or a phosphor resin to generate white light and to further render an uniform light-emitting area.

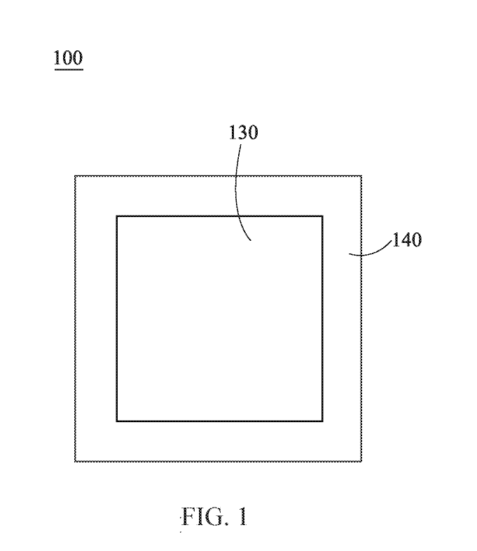

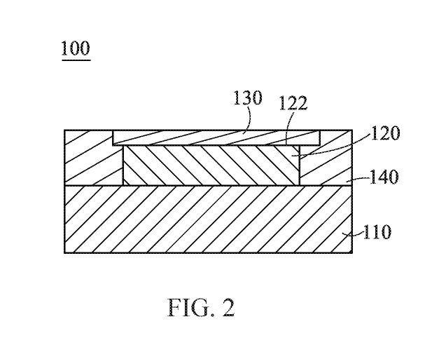

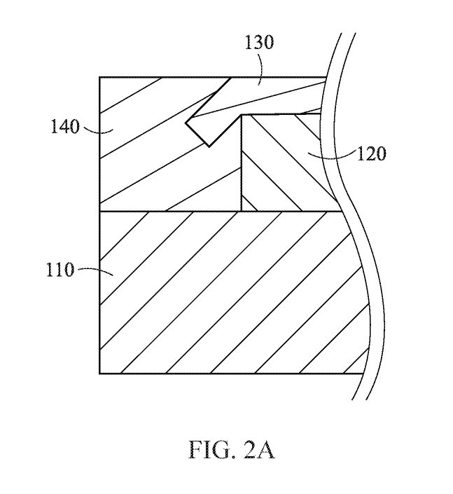

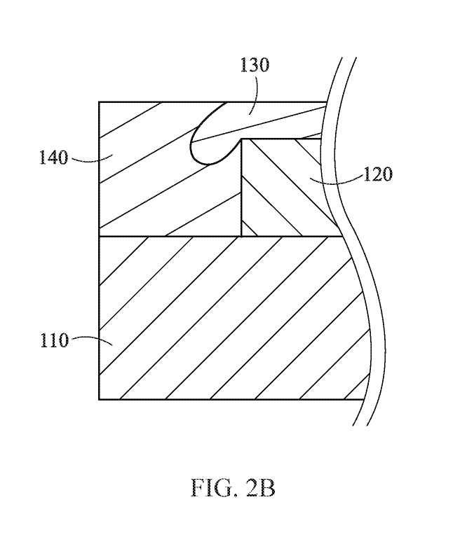

Firstly referring to FIG. 1 and FIG. 2, which respectively shows a top view and a cross-sectional view of an LED package 100 in accordance with a first implementation of the present disclosure. As shown in FIG. 1 and FIG. 2, the LED package 100 comprises a substrate 110, an LED chip 120, a phosphor sheet 130 and a first resin 140. The LED chip 120 is disposed on the substrate 110 and has an upper surface 122. The phosphor sheet 130 has a first area and through which the phosphor sheet 130 is affixed to the upper surface 122 of the LED chip 120. The first resin 140 is disposed on the substrate 110 and surround the LED chip 120 along with the phosphor sheet 130 with at least a part of the phosphor sheet being exposed.

In the present implementation, the applying area of the adhesive for affixing the phosphor sheet 130 to the LED chip 120 is smaller than or equal to an upper surface of the LED chip 120.

In the present implementation, the first area of the phosphor sheet 130 is slightly larger than the area of the upper surface 122 of the LED chip 120. That is, the periphery of the phosphor sheet 130 extends beyond the upper surface 122 of the LED chip 120 to ensure that all lights emitted from the LED chip 120 emit through the phosphor sheet 130 and excite the phosphor particle contained within to generate white light.

It shall be appreciated that, the first resin 140 is made of an opaque material in accordance with the first implementation of the present invention. Therefore, when the first resin 140 is disposed on the substrate 110 and surrounds the LED chip 120 along with the periphery of the phosphor sheet 130 with at least one part of the phosphor sheet 130 being exposed, the white light is only emitted through the at least one exposed part of the phosphor sheet 130.

Specifically, referring to FIG. 1 and FIG. 2. In the LED package 100 in accordance with the first implementation, the substrate 110 is below the LED chip 120, the phosphor sheet 130 is above the LED chip 120, and the first resin 140 surrounds the periphery of the LED chip 120 and the periphery of the phosphor sheet 130.

In other words, in the first implementation, the first resin 140 surrounding the periphery of the LED chip 120 and the periphery of the phosphor sheet 130 is not in contact with the upper surface 122 of the LED chip 120 that is used for emitting light. Thus, in the LED package 100 of the present implementation, the LED chip 120 is isolated from outside because it is covered by the substrate 110, the phosphor sheet 130 and the first resin 140. Moreover, the lights emitted from the LED chip 120 may only be emit through the phosphor sheet 130 and may be converted into the desired white light while phosphor particle contained in the phosphor sheet 130 is excited, and then the white light is emitted to outside.

Similarly, since the periphery of the phosphor sheet 130 is also covered by the opaque first resin 140, the excited light may be intensively emitted towards the direction away from the phosphor sheet 130.

It shall be particularly appreciated that, to achieve better bonding between the LED chip 120 and the phosphor sheet 130, the first area of the phosphor sheet 130 may be slightly larger than the upper surface 122 of the LED chip 120 as shown in FIG. 2A; and preferably, part of the first area of the phosphor sheet 130 that extends beyond the upper surface 122 of the LED chip 120 is inclined inwards towards the LED chip 120 to prevent the phosphor sheet 130 from being damaged or separated from the LED chip 120 due to thermal expansion and contraction or the contraction stress generated during the curing of the first resin 140 in the manufacturing process.

On the other hand, when the first area of the phosphor sheet 130 is slightly larger than the upper surface 122 of the LED chip 120, part of the first area of the phosphor sheet 130 that extends beyond the upper surface 122 of the LED chip 120 may also be a curved surface that is concave downwards as shown in FIG. 2B, and this can also prevent the phosphor sheet 130 from being damaged or separated from the LED chip 120 due to thermal expansion and contraction or the contraction stress generated during the curing of the first resin 140 in the manufacturing process.

Moreover, such arrangement, by making the phosphor sheet 130 overly cover the LED chip 120, can effectively ensure the lights of the LED chip 120 be emitted through the phosphor sheet 130 to generate desired white light no matter the lights are emitted from the upper surface 122 or from the side surfaces, thereby improving the illuminance and light uniformity of the LED package 100 of the present implementation.

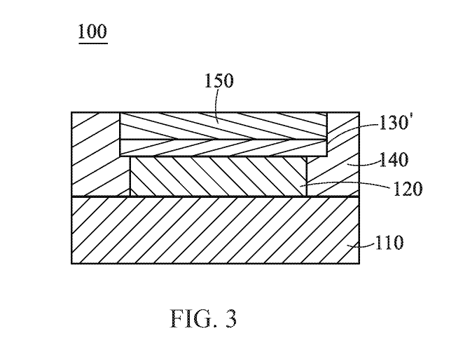

Next, referring to FIG. 3, which is a cross-sectional view of a second aspect of the LED package 100 according to the first implementation of the present disclosure. In the aspect shown in FIG. 3, the LED package 100 comprises a substrate 110, an LED chip 120, a translucent sheet 150 and a first resin 140. The LED chip 120 is disposed on the substrate 110, and the translucent sheet 150 is disposed on the substrate 110 and covers the LED chip 120. The first resin 140 is disposed on the substrate 110 and is adapted to surround a periphery of the translucent sheet 150 and expose at least a part of the translucent sheet 150. The translucent sheet 150 has at least one phosphor deposition sub-layer 130′, and the first resin 140 is not in contact with the LED chip 120.

Specifically, as shown in FIG. 3, the translucent sheet 150 is disposed on the upper surface of the LED chip 120. Because the periphery of the translucent sheet 150 is covered by the opaque first resin 140, the lights emitted from the LED chip 120 are emitted to the translucent sheet 150 and are converted to the desired white light after the phosphor deposition sub-layer 130′ in the translucent sheet 150 is excited, and then the white light is transmitted to the outside in a direction away from the phosphor sheet 120.

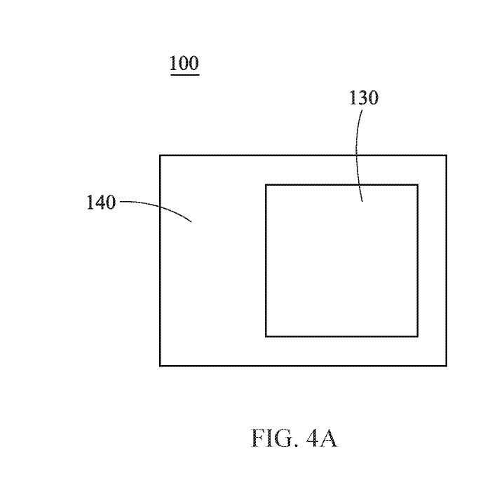

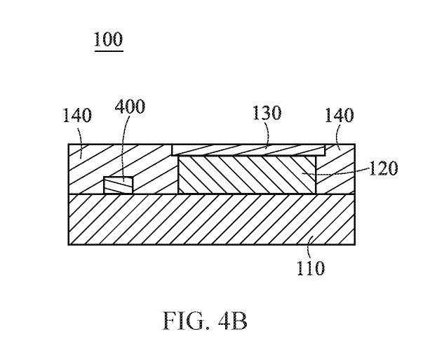

Next, please refer to FIG. 4A and FIG. 4B, which are respectively a top view and a cross-sectional view of a second implementation of an LED package according to the present disclosure.

As shown in FIG. 4A and FIG. 4B, the second implementation of the LED package 100 of the present disclosure, which is similar to the aforesaid first implementation of FIG. 1 and FIG. 2, may also comprise a substrate 110, an LED chip 120, a phosphor sheet 130 or a translucent sheet 150 having at least one phosphor deposition sub-layer 130′, and a first resin 140.

The difference between the first implementation and the second implementation of the LED package 100 lies in that: the LED package 100 of the second implementation further comprises a Zener Diode chip 400 to additionally provide a voltage stabilizing function for the LED package 100.

In detail, as shown in FIG. 4A and FIG. 4B, the Zener Diode chip 400 is disposed on the substrate 110 and is parallel to the LED chip 120 in the second implementation. The Zener Diode chip 400 may be electrically connected with the substrate 110 through wire bonding, soldering, or eutectic or flip chip technology. Additionally, as shown in FIG. 4B, because the Zener Diode chip 400 is covered by the first resin 140, the Zener Diode chip 400 is isolated from the outside after the first resin 140 is provided. Moreover, because the first resin 140 is made of an opaque material, the Zener Diode chip 400 cannot be seen from the top view of FIG. 4A.

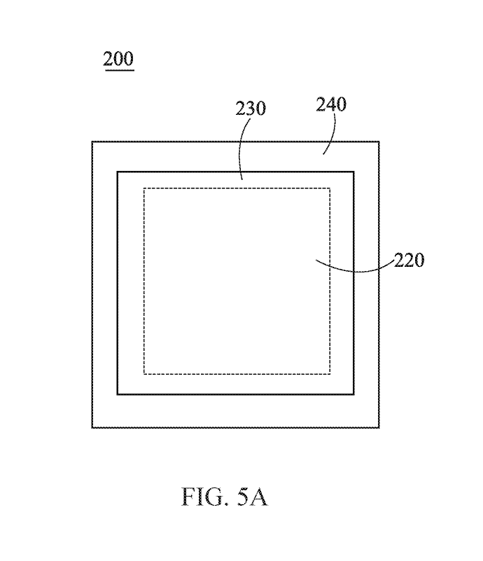

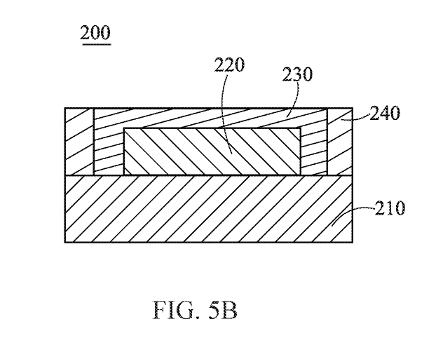

A top view and a cross-sectional view of a third implementation of an LED package according to the present disclosure are as shown in FIG. 5A and FIG. 5B. As shown in FIG. 5A and FIG. 5B, an LED package 200 of the third implementation comprises a substrate 210, an LED chip 220, a phosphor resin 230 and a first resin 240. The LED chip 220 is disposed on the substrate 210, and the phosphor resin 230 is disposed on the substrate 210 and is adapted to cover the LED chip 220. The first resin 240 is disposed on the substrate 210 and is adapted to surround a periphery of the phosphor resin 230 and expose at least a part of the phosphor resin 230 so that the first resin 240 is not in contact with the LED chip 220.

In the present implementation, the phosphor resin 230 is a resin doped with a phosphor material or is directly made of a phosphor material. Because the phosphor resin 230 is disposed on the substrate 210 and covers the LED chip 220, the LED chip 220 is isolated from the outside.

Furthermore, the first resin 240 is also made of an opaque material, and when the first resin 240 is disposed on the substrate 210 and is adapted to surround the periphery of the phosphor resin 230 and expose at least a part of the phosphor resin 230, the first resin 240 is not in contact with the LED chip 220 because the LED chip 220 is isolated from the outside by the substrate 210 and the phosphor resin 230.

In this way, because the LED chip 220 and the phosphor resin 230 are surrounded and covered by the opaque first resin 240, the white light generated after the phosphor resin 230 is excited by the lights emitted from the LED chip 220 will be intensively emitted in the direction perpendicular to and away from the phosphor resin 230.

It shall be appreciated that, in the third implementation, the phosphor resin 230 may have a rectangular cross section, a cross section that is narrower at the top thereof and wider at the bottom thereof or a trapezoid cross section to ensure centralization of the light-emitting surface and to improve the illuminance.

Thus, the LED package 200 of the third implementation has the following benefits: all the lights emitted from the LED chip 220 can be absorbed by the phosphor resin 230 to generate the desired white light; and a required height of the LED package 300 can be customized by directly changing the thickness of the phosphor resin 230 that is used, thereby simplifying the required processing procedures.

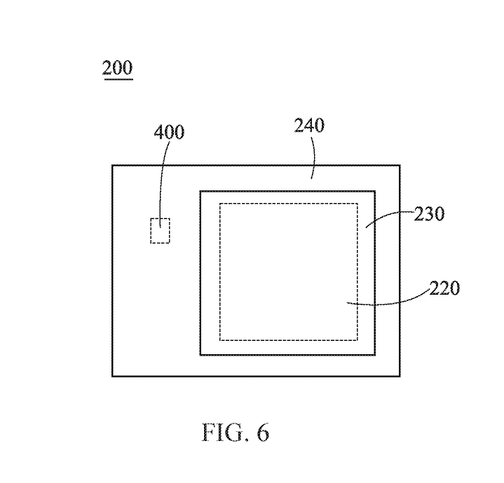

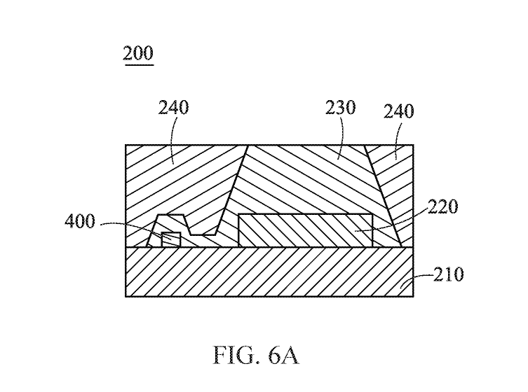

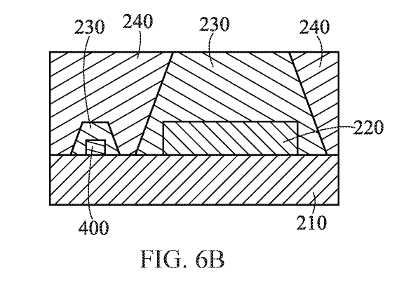

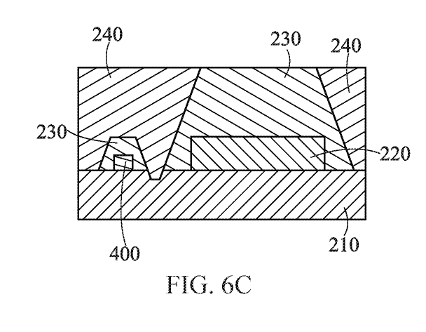

A top view and a cross-sectional view of a fourth implementation of an LED package according to the present disclosure are as shown in FIG. 6 and FIG. 6A. The LED package 200 of the fourth implementation is similar to that of the third implementation and may also comprise a substrate 210, an LED chip 220, a phosphor resin 230 and a first resin 240. The difference between the LED package 200 of the fourth implementation and that of the third implementation lies in that: the LED package 200 of the fourth implementation further comprises a Zener Diode chip 400.

In detail, in a first aspect of the fourth implementation as shown in FIG. 6A, the Zener Diode chip 400 is disposed on the substrate 210 adjacent to the LED chip 220 and is covered by the phosphor resin 230. Therefore, the Zener Diode chip 400 of the fourth implementation is also isolated from the outside because the Zener Diode chip 400 is also covered by the phosphor resin 230.

It shall be particularly appreciated that, in the first aspect of the fourth implementation shown in FIG. 6A, the phosphor resin 230 covering the Zener Diode chip 400 and the phosphor resin 230 covering the LED chip 220 communicate with each other. That is, the phosphor resin 230 disposed between the LED chip 220 and the Zener Diode chip 400 is continuous. In other words, in the cross-sectional view of FIG. 6A, the phosphor resin 230 covers the substrate 210 between the LED chip 220 and the Zener Diode chip 400 so that the first resin 240 is not in contact with the substrate 210 between the LED chip 220 and the Zener Diode chip 400.

A second aspect of the fourth implementation of the LED package according to the present disclosure is as shown in FIG. 6B. The difference between the second aspect and the aforesaid first aspect of the fourth implementation lies in that: the phosphor resin 230 covering the Zener Diode chip 400 and the phosphor resin 230 covering the LED chip 220 do not communicate with each other.

That is, as shown in a cross-sectional view of FIG. 6B, there is an gap between the phosphor resin 230 covering the LED chip 220 and the phosphor resin 230 covering the Zener Diode chip 400. Thus, the first resin 240 can fill the gap and be in contact with the substrate 210 between the LED chip 220 and the Zener Diode chip 400.

In this way, through the structural arrangement as shown in FIG. 6B, the lights emitted from the LED chip 220 only propagate in the phosphor resin 230 surrounding the LED chip 220 and cannot travel to the phosphor resin 230 surrounding the Zener Diode chip 400. Thereby, light loss can be avoided to further improve the illuminance.

A third aspect of the fourth implementation of the LED package according to the present disclosure is as shown in FIG. 6C. The difference between the third aspect and the first aspect of the fourth implementation lies in that: the phosphor resin 230 covering the Zener Diode chip 400 and the phosphor resin 230 covering the LED chip 220 do not communicate with each other, and moreover, a recessed portion 212 is further formed on the substrate 210 between the phosphor resin 230 covering the Zener Diode chip 400 and the phosphor resin 230 covering the LED chip 220, and the bottom of the recessed portion 212 may be in a chamfered form to actually avoid light loss and further improve the illuminance.

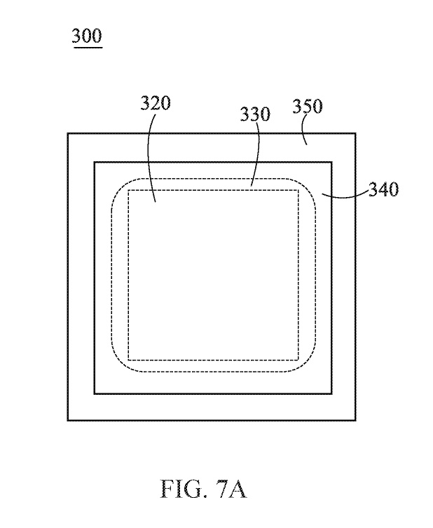

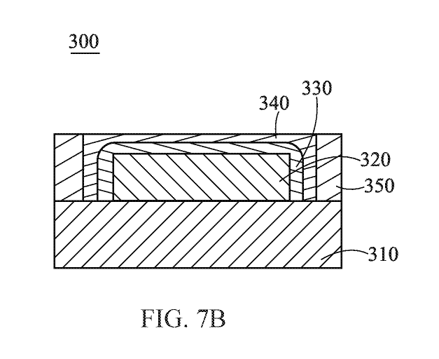

FIG. 7A and FIG. 7B are respectively a top view and a cross-sectional view of a fifth implementation of an LED package according to the present disclosure. As shown in FIG. 7A and FIG. 7B, an LED package 300 of the fifth implementation has a substrate 310, an LED chip 320, a phosphor coating 330, a transparent resin 340 and a first resin 350. The LED chip 320 is disposed on the substrate 310, the phosphor coating 330 covers the LED chip 320, and the transparent resin 340 is disposed on the substrate 310 and is adapted to cover the LED chip 320 and the phosphor coating 330. The first resin 350 is disposed on the substrate 310 and is adapted to surround the periphery of the transparent resin 340 and expose at least a part of the transparent resin 340, and the first resin 350 is not in contact with the LED chip 320.

In detail, in the present implementation, the phosphor coating 330 is made of a highly volatile and transparent coating doped with a phosphor material or is directly made of a phosphor material, and the phosphor coating 330 is adapted to cover the surface of the LED chip 320. That is, the phosphor coating 330 is in the form of a coating layer or a thin film, and it at least covers the upper surface of the LED chip 320.

The transparent resin 340 is a resin of high transmittance and is disposed on the substrate 310 and adapted to cover the LED chip 320 and the phosphor coating 330. Specifically, the transparent resin 340 covers the periphery and the upper surface of both the LED chip 320 and the phosphor coating 330 so that the LED chip 320 and the phosphor coating 330 are isolated from the outside. Thus, in the fifth implementation, the first resin 350 is not in contact with the LED chip 310.

Moreover, the benefits of using the phosphor coating 330 and the transparent resin 340 are as follows: the possible damage to the phosphor sheet as in the prior art can be avoided by coating the phosphor coating 330 on the LED chip 320, and a required height of the LED package 300 can be customized by controlling the thickness of the transparent resin 340.

On the other hand, the transparent resin 340 may also have a rectangular cross section, a cross section that is narrower at the top thereof and wider at the bottom thereof or a trapezoid cross section to ensure centralization of the light-emitting surface and improve the illuminance.

It shall be appreciated that, when the phosphor coating 330 is coated on the LED chip 320 to cover the upper surface of the LED chip 320 in practice, the phosphor coating 330, after being cured, is slightly collapsed to be attached on the surface of the LED chip 320 due to the action of gravity.

The difference between the LED package 300 of the fifth implementation and the LED package 100 of the first implementation lies in that: the LED package 300 of the fifth implementation uses the combination of the phosphor coating 330 and the transparent resin 340 instead of the phosphor sheet 130 comprised in the LED package 100 of the first implementation.

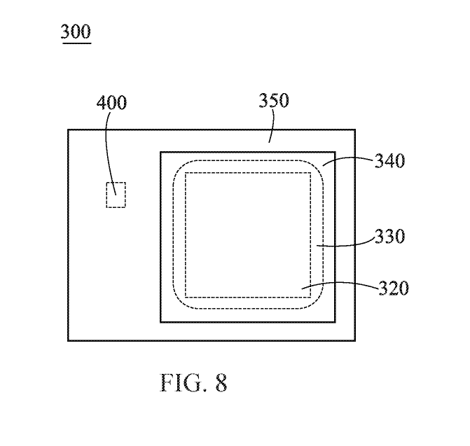

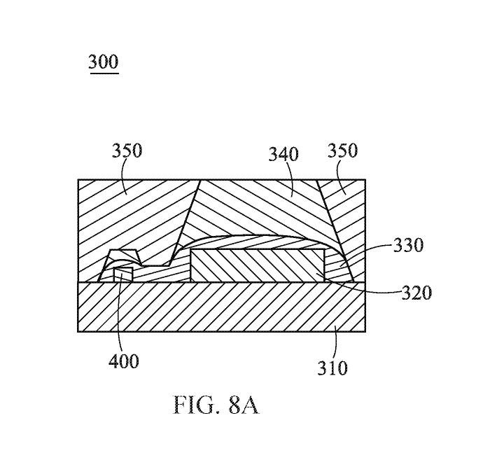

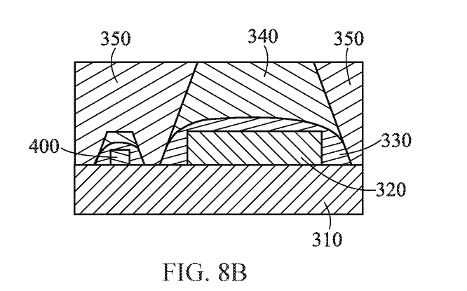

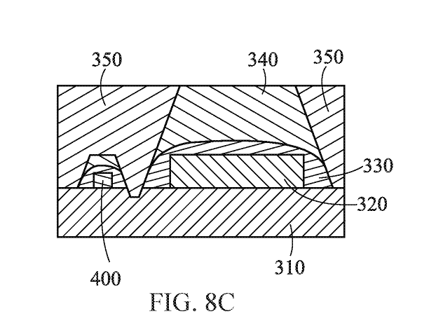

FIG. 8 and FIG. 8A are respectively a top view and a cross-sectional view of a sixth implementation of an LED package according to the present disclosure. The LED package 300 of the sixth implementation is similar to that of the fifth implementation, and it may also comprise a substrate 310, an LED chip 320, a phosphor coating 330, a transparent resin 340 and a first resin 350. The difference between the LED package 300 of the sixth implementation and that of the fifth implementation lies in that: the LED package 300 of the sixth implementation may further comprise a Zener Diode chip 400.

In detail, in a first aspect of the sixth implementation as shown in FIG. 8A, the Zener Diode chip 400 is disposed on the substrate 310, and the Zener Diode chip 400 can also be covered by the transparent resin 340 because it is disposed adjacent to the LED chip 320.

It shall be particularly appreciated that, in the first aspect of the sixth implementation shown in FIG. 8A, a portion of the transparent resin 340 covering the Zener Diode chip 400 and another portion of the transparent resin 340 covering the LED chip 320 link together. That is, the transparent resin 340 disposed between the LED chip 320 and the Zener Diode chip 400 is continuous. In other words, in the cross-sectional view of FIG. 8A, the transparent resin 340 covers the substrate 310 between the LED chip 320 and the Zener Diode chip 400 so that the first resin 350 is not in contact with the substrate 310 between the LED chip 320 and the Zener Diode chip 400.

A second aspect of the sixth implementation of the LED package according to the present disclosure is as shown in FIG. 8B. The difference between the second aspect and the aforesaid first aspect of the sixth implementation lies in that: a portion of the transparent resin 340 covering the Zener Diode chip 400 and another portion of the transparent resin 340 covering the LED chip 320 do not link together.

That is, as shown in a cross-sectional view of FIG. 8B, there is a gap between the transparent resin 340 covering the LED chip 320 and the transparent resin 340 covering the Zener Diode chip 400. Thus, the first resin 350 can fill the gap and be in contact with the substrate 310 between the LED chip 320 and the Zener Diode chip 400.

In this way, through the structural arrangement as shown in FIG. 8B, the lights emitted from the LED chip 320 only propagate in the transparent resin 340 surrounding the LED chip 320 and cannot travel to the transparent resin 340 surrounding the Zener Diode chip 400. Thereby, light loss can be avoided to further improve the illuminance.

A third aspect of the sixth implementation of the LED package according to the present disclosure is as shown in FIG. 8C. The difference between the third aspect and the aforesaid first aspect of the sixth implementation lies in that: a portion of the transparent resin 340 covering the Zener Diode chip 400 and another portion of the transparent resin 340 covering the LED chip 320 do not link together, and moreover, a recessed portion 312 is further formed on the substrate 310 between the transparent resin 340 covering the Zener Diode chip 400 and the transparent resin 340 covering the LED chip 320, and the bottom of the recessed portion 312 may be in a chamfered form to surely prevent the lights emitted by the LED chip 320 from traveling to the Zener Diode chip 400 to cause light loss and to further improve the illuminance.

The methods of fabrication an LED package and the operations involved will be described hereinafter.

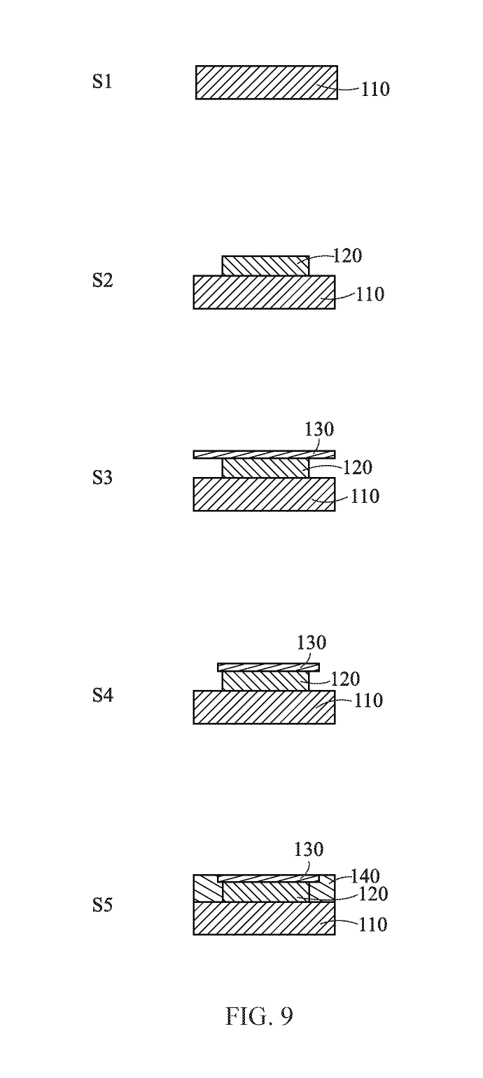

FIG. 9 shows a process of fabricating an LED package in accordance with a first implementation of the present disclosure. As shown in FIG. 9, the method for manufacturing the LED package 100 may comprise the following steps.

First, in step S1, a substrate 110 is provided. Next, in step S2, an LED chip 120 is disposed on the substrate 110 through adhesive, soldering, or die bonding. In step S3, a phosphor sheet 130 is affixed to an upper surface 122 of the LED chip 120. An area of the affixed phosphor sheet 130 is larger than an area of the upper surface 122 of the LED chip 120 (and is approximately equal to an area of the substrate 110). Then, in step S4, the phosphor sheet 130 is cut so that the area of the phosphor sheet 130 finally is slightly larger than the area of the upper surface 122 of the LED chip 120. Finally, in step S5, a first resin 140 is provided to cover the LED chip 120 along with the phosphor sheet 130 with at least a part of the phosphor sheet 130 being exposed. In this way, the LED package 100 as shown in FIG. 2 can be correspondingly obtained.

It shall be appreciated that, after the step S2, a phosphor sheet 130 of which the area is slightly larger than the area of the upper surface 122 of the LED chip 120 can be directly affixed on the LED chip 120, and thereby the step S3 is omitted and the step S4 is directly executed after the step S2.

Additionally in the step S4, when a pressure is applied to the phosphor sheet 130, the phosphor sheet 130 may be disposed on the upper surface 122 of the LED chip 120 in such a way that the phosphor sheet 130 is inclined inwards towards the LED chip 120 (as shown in FIG. 2A) or a curved surface that is concave downwards is formed by part of the phosphor sheet 130 that extends beyond the upper surface 122 of the LED chip 120 (as shown in FIG. 2B) under the pressure. This prevents the phosphor sheet 130 from being damaged or separated from the LED chip 120 due to thermal expansion and contraction or the contraction stress generated during the curing of the first resin 140 in the subsequent manufacturing process. Meanwhile, this can ensure that the lights of the LED chip 120 can be emitted to the phosphor sheet 130 to generate the desired white light no matter the lights are emitted from the upper surface 122 or from the side surfaces of the LED chip 120, thereby improving the illuminance and light uniformity of the LED package 100 of the present implementation.

Moreover, before the step S5 is executed, a translucent sheet 150 may be disposed on the phosphor sheet 130, and then a mold is used to apply a pressure to the translucent sheet 150, and next the first resin 140 is provided to cover the aforesaid LED chip 120, the phosphor sheet 130 and the translucent sheet 150 so that the LED package 100 can have the aforesaid structure as shown in FIG. 3. In other words, through the arrangement of the translucent sheet 150, the overall height of the LED package 100 can be adjusted depending on different customized requirements.

On the other hand, in the process of the step S5, a mold (not shown) may be used to apply a pressure to the phosphor sheet 130, and a gap formed between the mold and the substrate 110/the phosphor sheet 130 is filled with the first resin 140. In this way, after the mold is removed, the LED package 100 of the first implementation in this application is formed. Moreover, because the first resin 140 only covers the upper surface of the substrate 110, the periphery of the LED chip 120 and the periphery of the phosphor periphery 130, the first resin 140 does not shield the upper surface of the phosphor sheet 130.

In mass production of the LED package 100 as shown in FIG. 2, the steps of FIG. 9 may be adopted. First, a substrate 110 having a large area is provided, then a plurality of LED chips 120 are disposed on the substrate 110 in a matrix form, then a phosphor sheet 130 having an area approximately equal to the area of the substrate 110 is placed on the LED chips 120 and then cut into a plurality of small phosphor sheets 130, the first resin 140 is provided so that the first resin 140 covers the LED chips 120 and the phosphor sheets 130, and finally the overall structure is cut by a cutting tool into individual LED packages 100 as shown in FIG. 2.

Similar steps may also be adopted for mass production of the LED package 100 as shown in FIG. 3, and the only difference is a further step of disposing the translucent sheet 150, so this will not be further described herein.

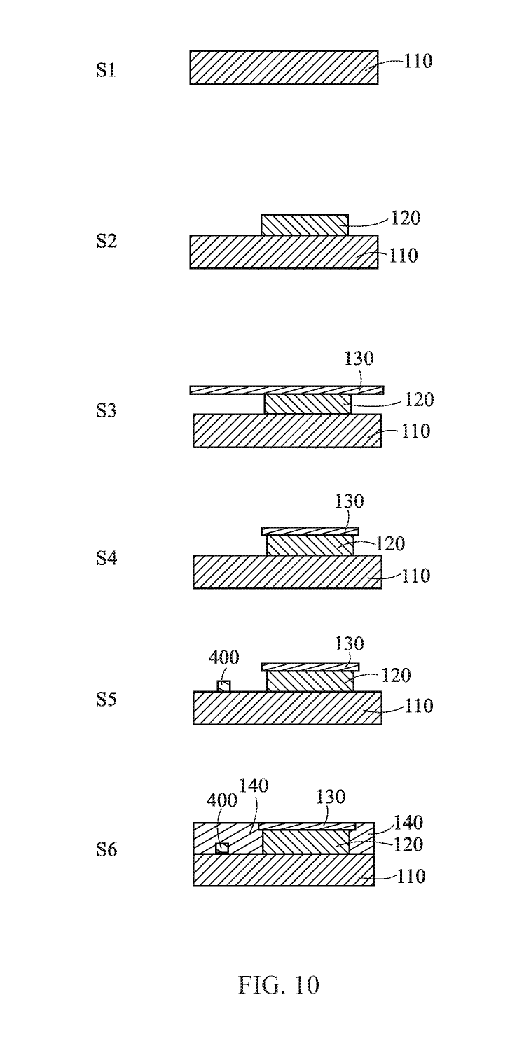

FIG. 10 shows a process of fabricating an LED package in accordance with a second implementation of the present disclosure. As shown in FIG. 10, the method for manufacturing the LED package 100 may comprise the following steps.

First, in step Si, a substrate 110 is provided. Next, in step S2, an LED chip 120 is disposed on the substrate 110 through adhesive, soldering, or die bonding. In step S3, a phosphor sheet 130 is affixed on an upper surface 122 of the LED chip 120. An area of the affixed phosphor sheet 130 is larger than an area of the upper surface 122 of the LED chip 120 (and is approximately equal to an area of the substrate 110). Then, in step S4, the phosphor sheet 130 is cut so that the area of the phosphor sheet 130 is slightly larger than the area of the upper surface 122 of the LED chip 120. In step S5, a Zener Diode chip 400 is disposed on the substrate 110. Finally, in step S6, a first resin 140 is provided to cover the LED chip 120, the phosphor sheet 130 and the Zener Diode chip 400, and to expose at least a part of the phosphor sheet 130. In this way, the LED package 100 as shown in FIG. 4A and FIG. 4B can be correspondingly obtained.

In other words, the steps of FIG. 10 are generally the same as those of FIG. 9, the only difference therebetween lies in that: the steps of FIG. 10 further include a step of disposing the Zener Diode chip 400 before providing the first resin 140. In addition to the aforesaid difference, the steps of FIG. 10 are the same as those of FIG. 9, and thus will not be further described herein.

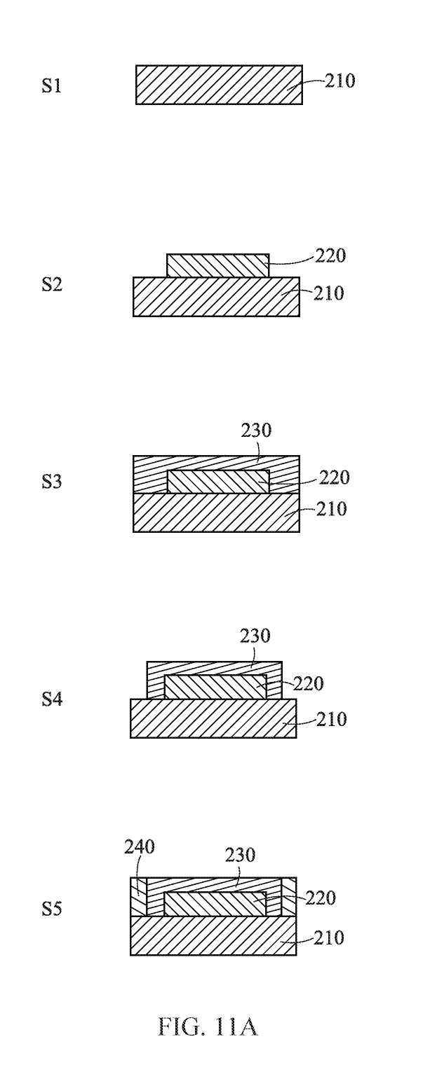

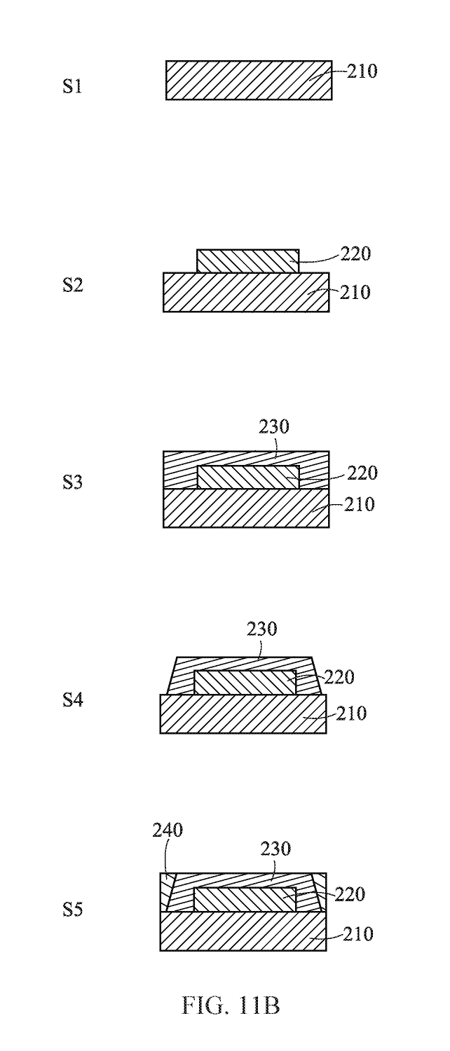

FIG. 11A is shows a process of fabricating an LED package in accordance with a third implementation of the present disclosure. As shown in FIG. 11A, the method for manufacturing the LED package 200 may comprise the following steps.

First, in step S1, a substrate 210 is provided. Next, in step S2, an LED chip 220 is disposed on the substrate 210. In step S3, a phosphor resin 230 is molded on the substrate 210 to cover the LED chip 220. In step S4, the phosphor resin 230 is cut along the periphery of the LED chip 220. In step S5, a first resin 240 is molded on the substrate 210 so that the first resin 240 covers the phosphor resin 230 and exposes at least a part of the phosphor resin 230, and the first resin 240 is not in contact with the LED chip 220.

In other words, after the step S5 of FIG. 11A is finished, the LED package 200 as shown in FIG. 5A and FIG. 5B is obtained.

It shall be noted that, in the step S4 of FIG. 11A, a cutting tool (not shown) is used to cut the phosphor resin 230 from top to bottom along the periphery of the LED chip 220, so the phosphor resin 230 still has side walls perpendicular to the substrate 210 after being cut in an ideal status.

However, as shown in FIG. 11 B, the cutting angle of the cutting tool may also be controlled so that the phosphor resin 230 surrounding the LED chip 220 has a cross section that is narrower at the top thereof and wider at the bottom thereof after being cut. This effectively controls the light path of the lights emitted from the LED chip 220 as they excite the phosphor resin 230, thereby avoid light loss and further improve the illuminance.

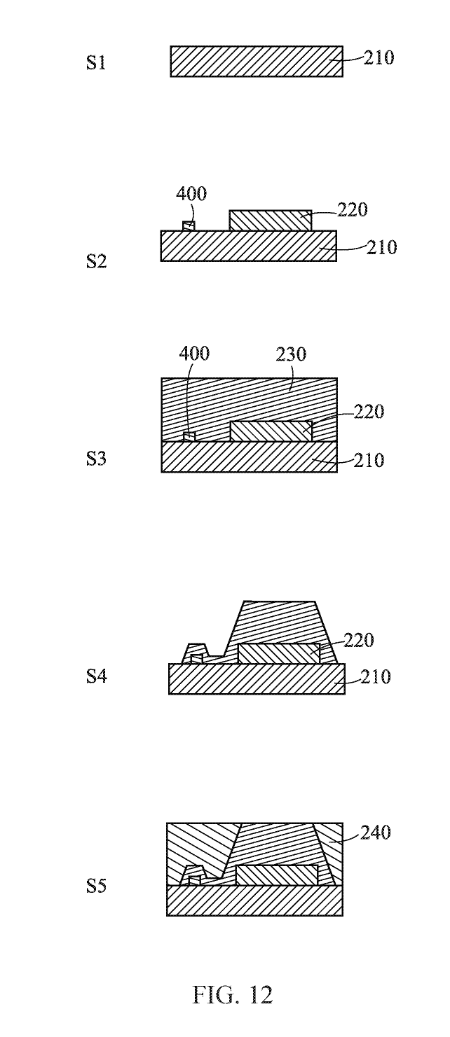

FIG. 12 shows a process of fabricating an LED package in accordance with a fourth implementation of the present disclosure. As shown in FIG. 12, the method for manufacturing the LED package 200 may comprise the following steps.

First, as shown in step S1, a substrate 210 is provided. As shown in step S2, an LED chip 220 and a Zener Diode chip 400 adjacent to the LED chip 220 are disposed on the substrate 210. As shown in step S3, a phosphor resin 230 is molded on the substrate 210 to cover the LED chip 220 and the Zener Diode chip 400. As shown in step S4, the phosphor resin 230 is cut along the periphery of the LED chip 220 and the periphery of the Zener Diode chip 400. Finally, as shown in step S5, a first resin 240 is molded on the substrate 210 so that the first resin 240 surrounds the periphery of the phosphor resin 240 and exposes at least a part of the phosphor resin 240 on the LED chip 220, and the first resin 240 is not in contact with the LED chip 220 and the Zener Diode chip 400.

It shall be appreciated that, in the step S4 of FIG. 12, when a cutting tool (not shown) is used to cut the phosphor resin 230 disposed between the LED chip 220 and the Zener Diode chip 400, the cutting tool is not in contact with the substrate 210. Therefore, similar to FIG. 6A described above, the phosphor resin 230 disposed between the LED chip 220 and the Zener Diode chip 400 is continuous.

As shown in the step S5 of FIG. 12, preferably, both the phosphor resin 230 covering the LED chip 220 and the phosphor resin 230 covering the Zener Diode chip 400 have a cross section that is narrower at the top thereof and wider at the bottom thereof in the present implementation, so white light generated after the lights emitted from the LED chip 220 excite the phosphor resin 230 will be intensively emitted from the LED package 200.

Additionally, when the cutting tool is controlled to cut the phosphor resin 230 in the step S5 of FIG. 12, the cutting tool may also cut until it is in contact with the substrate 210 or even cut into the substrate 210. Thus, the first resin 240 provided later can fill the space between the LED chip 220 and the Zener Diode chip 400 and make contact with the substrate 210 between the LED chip 220 and the Zener Diode chip 400, thereby presenting an LED package in the aforesaid form shown in FIG. 6B and FIG. 6C.

In this way, when the LED package 200 is in the form shown in FIG. 6B and FIG. 6C, the lights emitted from the LED chip 220 only propagate in the phosphor resin 230 surrounding the LED chip 220 and cannot travel to the phosphor resin 230 surrounding the Zener Diode chip 400. In other words, with such arrangement, light loss can be avoided to further improve the illuminance.

The aforesaid step S4 of cutting the phosphor resin 230 with a cutting tool may further be done by cutting the phosphor resin 230 in one time and cutting the phosphor resin 230 in several times. That is, if the cutting tool used is wide, then the unnecessary phosphor resin 230 can be cut and removed in one time. If the cutting tool used is narrow, then the unnecessary phosphor resin 230 can be cut and removed in several times.

It shall be noted that, even if the surface of the phosphor resin 230 above the Zener Diode chip 400 becomes serrated or wavy instead of being a flat surface shown in the step S4 in FIG. 12 when the phosphor resin 230 is cut and removed in several times, it still falls within the scope of the technical features claimed in this application.

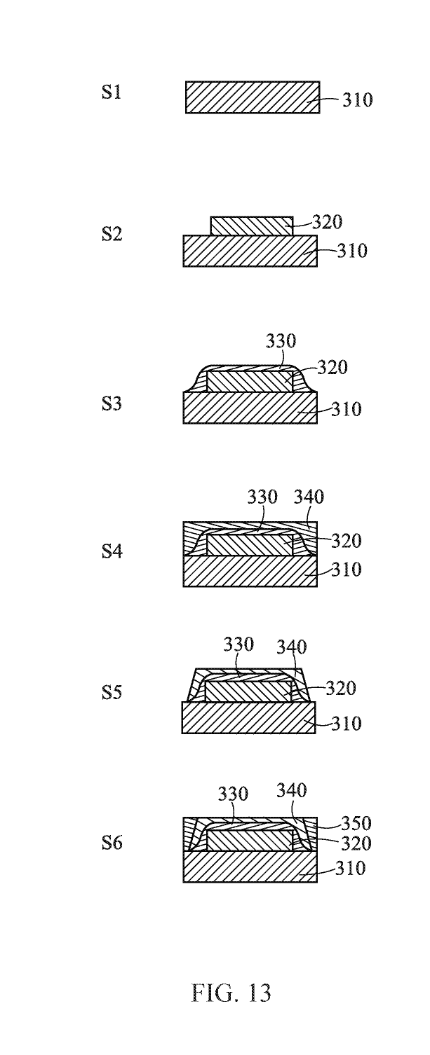

FIG. 13 is a schematic view of a method and steps thereof for manufacturing the fifth implementation of the LED package according to the present disclosure. As shown in FIG. 13, the method for manufacturing the LED package 300 may comprise the following steps.

First, as shown in step S1, a substrate 310 is provided. As shown in step S2, an LED chip 320 is disposed on the substrate 310. As shown in step S3, a phosphor coating 330 is coated on the LED chip 320. As shown in step S4, a transparent resin 340 is molded on the substrate 310 to cover the LED chip 320 and the phosphor coating 330. As shown in step S5, the transparent resin 340 is cut along the periphery of the LED chip 320. Finally, as shown in step S6, a first resin 350 is molded on the substrate 310 so that the first resin 350 surrounds the periphery of the transparent resin 340 and exposes at least a part of the transparent resin 340, and the first resin 350 is not in contact with the LED chip 320.

Therefore, similar to the description of the fifth implementation shown in FIG. 7A and FIG. 7B, the transparent resin 340 is a resin of high transmittance, so the LED chip 320 and the phosphor coating 330 are all isolated from outside and the first resin 350 is not in contact with the LED chip 310 when the transparent resin 340 is disposed on the substrate 310 and covers the LED chip 320 and the phosphor coating 330. Moreover, a required height of the LED package 300 can also be customized by directly changing the thickness of the transparent resin 340.

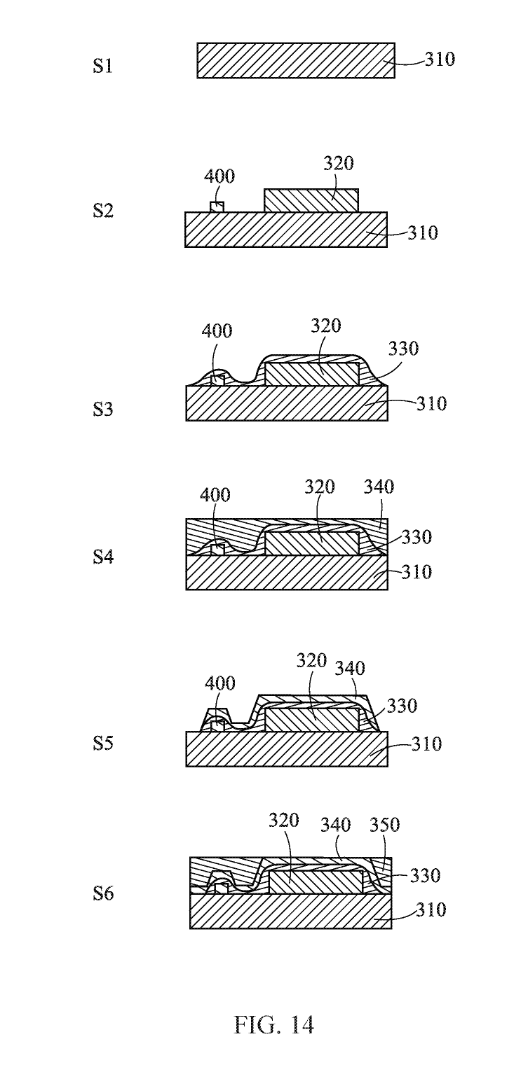

FIG. 14 is a schematic view of a method and steps thereof for manufacturing the sixth implementation of the LED package according to the present disclosure. As shown in FIG. 14, the method for manufacturing the LED package 300 may comprise the following steps.

First, as shown in step S1, a substrate 310 is provided. As shown in step S2, an LED chip 320 and a Zener Diode chip 400 adjacent to the LED chip 320 are disposed on the substrate 310. As shown in step S3, a phosphor coating 330 is coated on the LED chip 320. As shown in step S4, a transparent resin 340 is molded on the substrate 310 to cover the LED chip 320 and the Zener Diode chip 400. As shown in step S5, the transparent resin 340 is cut along the periphery of the LED chip 310 and the periphery of the Zener Diode chip 400. Finally, as shown in step S6, a first resin 350 is molded on the substrate 310 so that the first resin 350 surrounds the periphery of the transparent resin 340 and exposes at least a part of the transparent resin 340 on the LED chip 320, and the first resin 350 is not in contact with the LED chip 320 and the Zener Diode chip 400.

Therefore, similar to the description of the sixth implementation shown in FIG. 8 and FIG. 8A, the transparent resin 340 is a resin of high transmittance, so the LED chip 320, the Zener Diode chip 400 and the phosphor coating 330 are all isolated from the outside and the first resin 350 is not in contact with the LED chip 310 and the Zener Diode chip 400 when the transparent resin 340 is disposed on the substrate 310 and covers the LED chip 320, the Zener Diode chip 400 and the phosphor coating 330. Meanwhile, a required height of the LED package 300 can also be customized by directly changing the thickness of the transparent resin 340.

Additionally, similar to FIG. 12, when the cutting tool is controlled to cut the transparent resin 340 in the step S5 of FIG. 13, the cutting tool may also cut until it is in contact with the substrate 310 or even cut into the substrate 310. Thus, the first resin 350 provided later can fill the space between the LED chip 320 and the Zener Diode chip 400 and be in contact with the substrate 310 between the LED chip 320 and the Zener Diode chip 400, thereby presenting an LED package in the aforesaid form shown in FIG. 8B and FIG. 8C.

In this way, when the LED package is in the form as shown in FIG. 8B and FIG. 8C, the lights emitted from the LED chip 320 only propagate in the transparent resin 340 surrounding the LED chip 320 and cannot travel to the transparent resin 340 surrounding the Zener Diode chip 400. In other words, with such arrangement, light loss can be avoided to further improve the illuminance.

According to the above descriptions, all the LED packages disclosed in the implementations of the present disclosure can be produced by machines required in the current processes. Meanwhile, the LED packages can also provide a more uniform light-emitting area, prevent the phosphor sheet from being damaged or separated from the LED chip, improve the reliability of products and provide better protection for the LED chip and the Zener Diode chip.

### Additional Notes

Implementations of the present disclosure are not limited to those described herein. The actual design and implementation of each component of the LED package in accordance with the present disclosure may vary from the implementations described herein. Those ordinarily skilled in the art may make various deviations and improvements based on the disclosed implementations, and such deviations and improvements are still within the scope of the present disclosure. Accordingly, the scope of protection of a patent issued from the present disclosure is determined by the claims as follows.

In the above description of exemplary implementations, for purposes of explanation, specific numbers, materials configurations, and other details are set forth in order to better explain the present disclosure, as claimed. However, it will be apparent to one skilled in the art that the claimed subject matter may be practiced using different details than the exemplary ones described herein. In other instances, well-known features are omitted or simplified to clarify the description of the exemplary implementations.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts and techniques in a concrete fashion. The term “techniques,” for instance, may refer to one or more devices, apparatuses, systems, methods, articles of manufacture, and/or computer-readable instructions as indicated by the context described herein.

As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more,” unless specified otherwise or clear from context to be directed to a singular form.

For the purposes of this disclosure and the claims that follow, the terms “coupled” and “connected” may have been used to describe how various elements interface. Such described interfacing of various elements may be either direct or indirect.

What is claimed is:

1. A light emitting diode (LED) package, comprising:
a substrate;
an LED chip disposed on the substrate;
an adhesive;
a phosphor sheet having a first area and affixed on an upper surface of the LED chip via the adhesive; and
a first resin disposed on the substrate and adapted to surround a periphery of the LED chip and a periphery of the phosphor sheet to expose at least a part of the phosphor sheet,
wherein a diffusion area of the adhesive is not larger than an area of the upper surface of the LED chip when the phosphor sheet is affixed on the LED chip via the adhesive.

2. The LED package of claim 1, wherein the first area of the phosphor sheet is larger than the upper surface of the LED chip.

3. The LED package of claim 2, wherein a part of the first area of the phosphor sheet extends beyond the upper surface of the LED chip and is inclined inwards towards the LED chip.

4. The LED package of claim 2, wherein a part of the first area of the phosphor sheet extends beyond the upper surface of the LED chip and is a curved surface that is concave downward.

5. The LED package of claim 1, further comprising a Zener Diode chip disposed on the substrate and covered by the first resin.

6. The LED package of claim 1, wherein the phosphor sheet comprises at least one phosphor deposition sub-layer.

7. A light emitting diode (LED) package, comprising:
a substrate;
an LED chip disposed on the substrate;
a phosphor resin disposed on the substrate to cover the LED chip; and
a first resin disposed on the substrate to surround a periphery of the phosphor resin and expose at least a part of the phosphor resin, wherein the first resin is not in contact with the LED chip.

8. The LED package of claim 7, wherein the phosphor resin has a cross section that is narrower at a top thereof and wider at a bottom thereof.

9. The LED package of claim 7, further comprising a Zener Diode chip disposed on the substrate adjacent to the LED chip and covered by the phosphor resin.

10. The LED package of claim 9, wherein a portion of the phosphor resin covering the Zener Diode chip and another portion of the phosphor resin covering the LED chip link to each other.

11. The LED package of claim 9, wherein a portion of the phosphor resin covering the Zener Diode chip and another portion of the phosphor resin covering the LED chip do not link to each other.

12. The LED package of claim 9, wherein a recessed portion is formed on the substrate between a portion of the phosphor resin covering the Zener Diode chip and another portion of the phosphor resin covering the LED chip.

13. The LED package of claim 12, wherein a bottom of the recessed portion is in a chamfered form.

14. A light emitting diode (LED) package, comprising:
a substrate;
an LED chip being disposed on the substrate;
a phosphor coating coated on a surface of the LED chip;
a transparent resin disposed on the substrate to cover the LED chip and the phosphor coating; and
a first resin disposed on the substrate to surround a periphery of the transparent resin and expose at least a part of the transparent resin, wherein the first resin is not in contact with the LED chip.

15. The LED package of claim 14, wherein the transparent resin has a cross section that is narrower at a top thereof and wider at a bottom thereof.

16. The LED package of claim 14, further comprising a Zener Diode chip disposed on the substrate adjacent to the LED chip and covered by the transparent resin.

17. The LED package of claim 16, wherein a portion of the transparent resin covering the Zener Diode chip and another portion of the transparent resin covering the LED chip link to each other.

18. The LED package of claim 16, wherein a portion of the transparent resin covering the Zener Diode chip and another portion of the transparent resin covering the LED chip do not link to each other.

19. The LED package of claim 16, wherein a recessed portion is formed on the substrate between a portion of the transparent resin covering the Zener Diode chip and another portion of the transparent resin covering the LED chip.

20. The LED package of claim 19, wherein a bottom of the recessed portion is in a chamfered form.
